(19) United States
(12) Patent Application Publication
(10) Pub. No.: US 2008/0142193 A1
(43) Pub. Date: Jun. 19, 2008

(54) METHOD OF MANUFACTURING A HEAT DISSIPATION DEVICE AND A HEAT DISSIPATION DEVICE OBTAINED THEREBY

(75) Inventors: WEI LI, Shenzhen (CN); GEN-PING DENG, Shenzhen (CN); YI-QIANG WU, Shenzhen (CN)

Correspondence Address: PCE INDUSTRY, INC.;ATT. CHENG-JU CHIANG, 458 E. LAMBERT ROAD, FULLERTON, CA, 92835, US

(73) Assignee: FOXCONN TECHNOLOGY CO., LTD., Tu-Cheng (TW)

(21) Appl. No.: 11/681,724

(22) Filed: Mar. 2, 2007

(30) Foreign Application Priority Data
Dec. 13, 2006 (CN) 200610157526.6

(51) Int. Cl. B21D 53/06; H05K 7/20

(52) U.S. Cl. 165/80.3; 29/890.046; 361/700; 165/104.33

(57) ABSTRACT

A method of manufacturing a heat dissipation device, the method includes the steps of: a) affording a base, a plurality of fins, a plurality of flakes and solder, wherein the base includes a soldering face at a top surface thereof and defines a plurality of through holes therein; b) adhering the flakes to the soldering face of the base for covering the through holes; c) placing the solder onto the soldering face of the base and placing the fins onto the soldering face, whereby the solder is sandwiched between the base and the fins; d) heating the heat dissipation device at a determined temperature to melt the solder; and e) cooling the heat dissipation device to solder the fins onto the base.

### BACKGROUND OF THE INVENTION

1. Field of the Invention

The present invention relates to a method of manufacturing a heat dissipation device, and more particularly to a method of manufacturing a heat dissipation device which is used to remove the heat from an electronic component. The present invention is also related to a heat dissipation device obtained by the method.

2. Description of Related Art

To keep electronic components operating normally, heat generated by the electronic components must be removed away. Typically, a heat sink is attached to an outer surface of the electronic components to absorb heat from the electronic components, and the heat absorbed by the heat sink is then dissipated into the ambient air.

Conventionally, the heat sink is mounted on a printed circuit board and comprises a base and a plurality of fins mounted on the base. A plurality of threaded holes is defined through the base. A plurality of screws extends through the printed circuit board and the base in series to be engaged in the corresponding threaded holes for mounting the heat sink on the electronic component on the printed circuit board. In this related art, the fins are soldered to the base. However, during the soldering process the liquid solder may flow through the threaded holes of the base of the heat sink, which may hamper the screws from being threaded through the threaded holes.

A solution for preventing the solder from flowing through the threaded holes before assembly of the heat sink is needed.

### SUMMARY OF THE INVENTION

A method of manufacturing a heat dissipation device in accordance with a preferred embodiment of the present invention comprises the following steps: a) affording a base, a plurality of fins, heat pipes, a plurality of flakes and solder, wherein the base includes a soldering face at a top surface thereof and defines a plurality of through holes therein; b) adhering the flakes to the soldering face of the base for covering the through holes; c) placing the solder onto the soldering face of the base and placing the heat pipes and the fins onto the soldering face, whereby the solder is sandwiched between the base and the fins and between the base and the heat pipes; d) heating the heat dissipation device at a determined temperature to melt the solder; and e) cooling the heat dissipation device to solder the fins and the heat pipes onto the base.

### BRIEF DESCRIPTION OF THE DRAWINGS

Many aspects of the present heat dissipation device can be better understood with reference to the following drawings. The components in the drawings are not necessarily drawn to scale, the emphasis instead being placed upon clearly illustrating the principles of the present heat dissipation device. Moreover, in the drawings, like reference numerals designate corresponding parts throughout the several views. Other advantages and novel features will become more apparent from the following detailed description of preferred embodiment when taken in conjunction with the accompanying drawings, in which:

FIG. 1 is an exploded, isometric view of a heat dissipation device in accordance with a preferred embodiment of the present invention;

FIG. 2 is an partially assembled view of FIG. 1; and

FIG. 3 is an assembled view of FIG. 1.

### DETAILED DESCRIPTION OF THE INVENTION

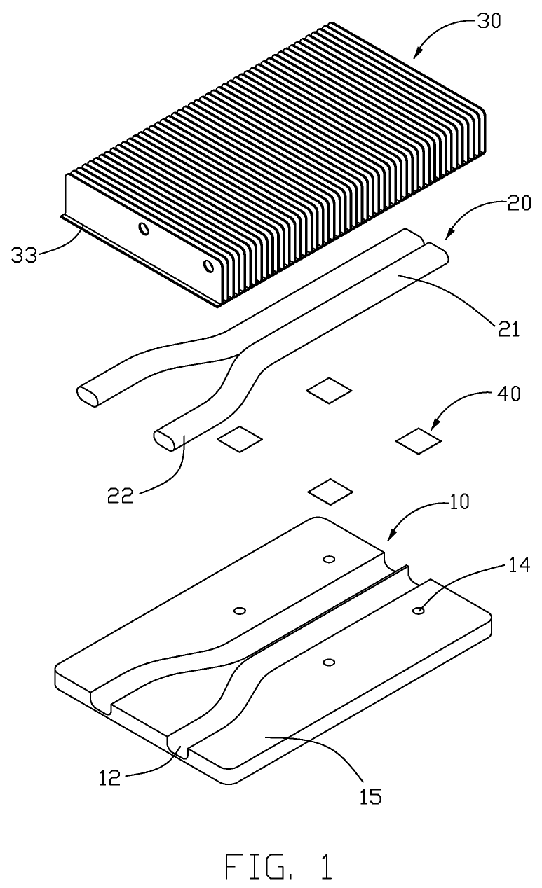

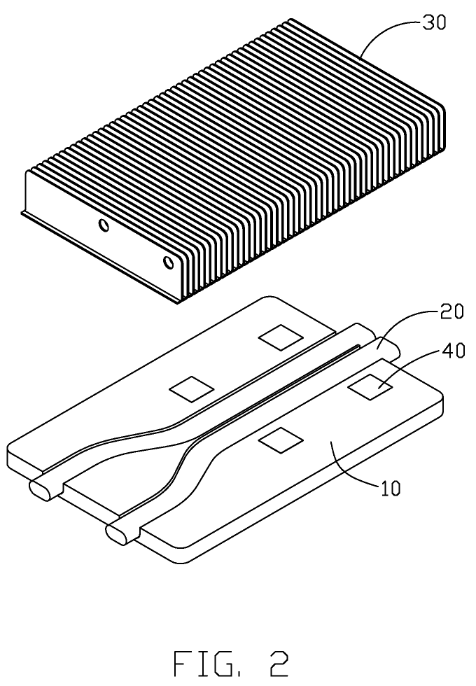

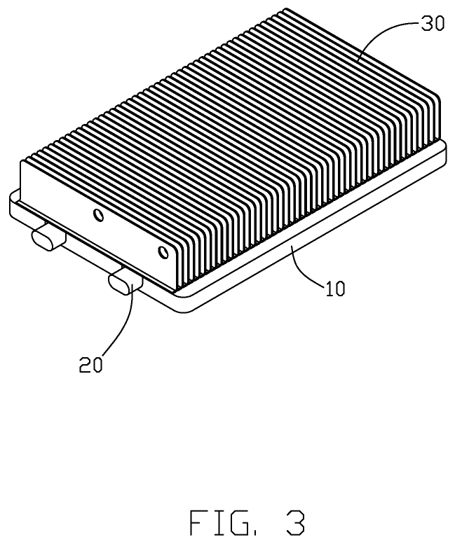

Referring to FIGS. 1-3, a method of manufacturing a heat dissipation device (not labeled) comprises a step: a) affording a base 10, two heat pipes 20, a plurality of fins 30, a plurality of flakes 40 and solder (not shown).

The base 10 has a rectangular configuration. The base 10 has a bottom face (not labeled) for contacting with a heat-generating electronic device mounted on a printed circuit board, such as a CPU (not shown) and a soldering face 15 opposite to the bottom face. The base 10 has two grooves 12 defined in the base 10 at the soldering face 15 thereof. The grooves 12 longitudinally extend along a front-to-rear direction at the soldering face 15. The grooves 12 are adjacent to each other at a rear side and apart at a front side in a manner such that the grooves 12 have a substantially Y-shaped configuration. Four through holes 14 are threaded holes, which are defined through the base 10 from top to bottom for providing passage of screws (not shown) after the base 10, the heat pipes 20, the flakes 40 and the fins 30 are assembled together.

The heat pipes 20 are flat and parallel to the base 10. The heat pipes 20 form a Y-shaped configuration together, corresponding to the grooves 12. A cross section of each heat pipe 20 is approximately elliptical. The heat pipes 20 comprise evaporating portions 21 and condensing portions 22 connecting with the evaporating portions 21. The evaporating portions 21 are adjacent to each other and the condensing portions 22 are apart to each other. The evaporating portions 21 are located between the through holes 14. A depth of each groove 12 is slightly greater than a thickness of each heat pipe 20. This difference in dimension between the groove and the heat pipe 20 will accommodate the layer of solder. As such, after the heat pipes 20 are positioned in the grooves 12 and the solder is filled between the heat pipes 20 and the grooves 12, an exposed outer surface of each heat pipe 20 is coplanar with the soldering face 15 of the base 10.

The flakes 40 are made of high temperature resistance material and have sticky layers on bottom faces thereof to be attached to the soldering face 15 of the base 10 for covering the through holes 14, whereby the solder cannot penetrate into the through holes 14 when it is heated.

The fins 30 are made of metal sheets. The fins 30 are oriented perpendicular to the base 10 and parallel to each other. Each fin 30 forms a flange 33 perpendicularly bent from a bottom edge thereof. The flanges 33 of the fins 30 act as soldering portions to be soldered on the base 10.

The method of manufacturing the heat dissipation device further comprises the following steps:

b) adhering the flakes 40 to the soldering face 15 of the base 10 for covering the through holes 14;

c) placing the solder on the soldering face 15 of the base 10 and the grooves 12, and placing the heat pipes 20 in the grooves 12, and placing the fins 30 onto the soldering face 15, so that the solder is sandwiched between the base 10, the heat pipes 20 and the fins 30 after they are assembled;

d) heating the heat dissipation device at a determined temperature to melt the solder;

e) cooling the heat dissipation device to solder the fins 30 and the heat pipes 20 onto the base 10.

Now, all processes of manufacturing the heat dissipation device have completed. The flakes 40 cover the ports of the holes 14 at the soldering face 15, whereby the opposing ends of the holes 14 can engage with the screws for holding the base 10 on the CPU by extending the screws from a bottom of the printed circuit board upwardly through the printed circuit board into the through holes 14 to threadedly engage in the through holes 14 of the base 10.

It is believed that the present embodiments and their advantages will be understood from the foregoing description, and it will be apparent that various changes may be made thereto without departing from the spirit and scope of the invention or sacrificing all of its material advantages, the examples hereinbefore described merely being preferred or exemplary embodiments of the invention.

What is claimed is:

1. A method of manufacturing a heat dissipation device, the method comprising the steps of:
a) affording a base, a plurality of fins, a plurality of flakes and solder, wherein the base includes a soldering face at a top surface thereof and defines a plurality of through holes therein;
b) adhering the flakes to the soldering face of the base for covering the through holes;
c) placing the solder onto the soldering face of the base and placing the fins onto the soldering face, whereby the solder is sandwiched between the base and the fins;
d) heating the heat dissipation device at a determined temperature to melt the solder; and
e) cooling the heat dissipation device to solder the fins onto the base.

2. The method of claim 1, wherein the base defines at least a groove therein at the soldering face thereof for receiving at least a heat pipe.

3. The method of claim 2, wherein a depth of the at least a groove is slightly greater than a thickness of the at least a heat pipe.

4. The method of claim 2, wherein the at least a heat pipe is flat.

5. The method of claim 2, wherein an exposed outer surface of the at least a heat pipe is coplanar with the soldering face of the base.

6. The method of claim 2, wherein the at least a groove includes two grooves longitudinally extending along a front-to-rear direction of the soldering face to form a substantially Y-shaped configuration.

7. The method of claim 6, wherein the at least a heat pipe includes two heat pipes each being curved, and wherein the heat pipes have evaporating portions adjacent to each other and condensing portions apart from each other.

8. The method of claim 2, wherein the base, the at least a heat pipe and the fins are soldered together.

9. The method of claim 1, wherein the flakes are made of high temperature resistance material.

10. The method of claim 1, wherein the fins are made of metal sheets, oriented perpendicular to the base and parallel to each other.

11. The method of claim 1, wherein the through holes form inner threads therein.

12. A heat dissipation device comprising:
a base having a bottom face adapted for thermally connecting with a heat-generating electronic component and a top face opposite the bottom face;
a plurality of through holes extending through the base from the top face to the bottom face, adapted for receiving fasteners for fastening the heat dissipation device to a printed circuit board;
a plurality of flakes attached to the top face of the base and covering top openings of the through holes;
a plurality of fins on the top face of the base; and
solder between the top face of the base and the plurality of fins and soldering the fins to the top face of the base.

13. The heat dissipation device of claim 12 further comprising heat pipes embedded in the top face of the base, the heat pipes having evaporating portions around which the through holes are located, and condensing portions, the evaporating portions being close to each other, the condensing portions being separated from each other.

14. The heat dissipation device of claim 12, wherein the through holes are threaded holes.

15. The heat dissipation device of claim 13, wherein the through holes are threaded holes.

16. The heat dissipation device of claim 12, wherein the fins each have a lower horizontal flange soldered to the top face of the base.

17. The heat dissipation device of claim 12, wherein the flakes are used for preventing the solder from entering the through holes via the top openings thereof.
